(19) United States
(12) Patent Application Publication
(10) Pub. No.: US 2023/0335198 A1
(43) Pub. Date: Oct. 19, 2023

(54) SEMICONDUCTOR DEVICE

(71) Applicant: RENESAS ELECTRONICS CORPORATION, Tokyo (JP)

(72) Inventor: Hirofumi HEBISHIMA, Tokyo (JP)

(21) Appl. No.: 18/299,332

(22) Filed: Apr. 12, 2023

(30) Foreign Application Priority Data
Apr. 13, 2022 (JP) 2022-065958

(51) Int. Cl. G11C 16/16; G11C 16/34; G11C 16/32

(52) U.S. Cl. CPC G11C 16/16; G11C 16/3413; G11C 16/32

(57) ABSTRACT

A semiconductor device having an electrically writable or erasable non-volatile memory and a control circuit for executing mode control of a write operation and an erase operation of the non-volatile memory, in which the non-volatile memory has a rewrite suspension/recovery control circuit: responding to a suspension request signal from the control unit that requests a suspension of a rewrite operation; responding to an operation for suspending an application of a write voltage or an erase voltage and a recovery request signal from the control unit that requests a recovery from the suspension of the rewrite operation; controlling an operation for recovery from the suspension of the voltage application; and outputting a rewrite interruption/return control circuit that outputs to the control circuit a voltage application stop flag at a voltage application stop of the write voltage or erase voltage, and a rewrite information holding circuit that holds write position information for identifying a selection line to which a write voltage is applied at a response time of a suspension request signal.

### CROSS-REFERENCE TO RELATED APPLICATION

The present application claims priority from Japanese Patent Application No. 2022-065958 filed on Apr. 13, 2022, the content of which is hereby incorporated by reference into this application.

### BACKGROUND

The present disclosure relates to a semiconductor device, more particularly, to a technique effectively applied to a semiconductor device including a nonvolatile memory.

In recent years, MCUs (Micro Control Units) need to handle multi-CPU (Central Processing Unit) cores and OTA (Over The Air) functions. Under such circumstances, a competition frequency of write requests and erase requests to the nonvolatile memory becomes significant. Specifically, the number of CPU cores becomes larger than the number of flash banks due to multiple CPU cores, and competition for write requests or erase requests to the same bank may occur frequently. In addition, by handling the OTA function, updating of the firmware becomes essential, and conflicts with write requests and erase requests may frequently occur in order to record field information of a vehicle or the like.

For example, Patent Document 1 (Japanese Patent Application Laid-open No. 2008-34045) discloses a technique for shortening a transition time from supply of a suspended instruction due to an interrupt during a write operation or erase operation to actual suspension. Specifically, in response to an interrupt command during a write operation or an erase operation, application of the write voltage or erase voltage is asynchronously canceled, which realizes shortening of a writing or erasing prohibition period (interruption time).

### SUMMARY

In spite of the devisal of the operations as described above, it becomes necessary to apply the write voltage or erase voltage to the same region again in returning from the write operation or erase operation, so that for insuring relativity of the non-volatile memory, the suspended instruction has been limited to one use. Therefore, interruption times for second and subsequent interruption processings cannot be reduced, and a response to the second and subsequent suspended interruptions is delayed. However, as described above, when it becomes essential to handle the multiple CPU cores and OTA (Over-The-Air) functions, it is assumed that conflicts for the write requests and the erase requests may occur frequently. In this case, it becomes difficult for the conventional technology to quickly respond to the suspension processings that occurs highly frequently while insuring the reliability of the non-volatile memory.

This disclosure has been made in view of this. One of the objects is to provide a semiconductor device capable of responding quickly to suspension processings that occur highly frequently while insuring reliability of a nonvolatile memory. Other problems and novel features will become apparent from the description of the specification and the accompanying drawings.

A brief outline of typical inventions disclosed in the present application is as follows. A representative semiconductor device includes an electrically writable or erasable non-volatile memory and a control circuit for executing mode control of a write operation and an erase operation of the non-volatile memory,

in which the non-volatile memory includes:
a rewrite suspension/recovery control circuit: responding to a suspension request signal from the control unit that requests a suspension of a rewrite operation containing at least one of the write operation and the erase operation; responding to an operation for suspending an application of a write voltage or an erase voltage and a recovery request signal from the control unit that requests a recovery from the suspension of the rewrite operation; controlling an operation for recovery from the suspension of the application of the rewrite voltage or erase voltage; and outputting a rewrite interruption/return control circuit that outputs to the control circuit a voltage application stop flag at a voltage application stop of the write voltage or erase voltage, and
a rewrite information holding circuit that holds write position information for identifying a selection line to which a write voltage is applied at a response time of a suspension request signal or erase position information for identifying a selection line to which an erase voltage is applied at the response time of the suspension request signal, and
in which the control unit responses to a suspension instruction when the non-volatile memory is in a write mode or an erase mode, transmits the suspension request signal of write to the rewrite suspension/recovery control unit, responds to a recovery instruction of the write mode or erase mode of the non-volatile memory suspended by the suspension request signal, and outputs a recovery request signal of the write to the rewrite suspension/recovery control unit when the voltage application stop flag outputted from the rewrite suspension/recovery control unit is active.

According to one embodiment, it is possible to provide a semiconductor device capable of quickly responding to frequently occurring suspension processings while ensuring the reliability of the non-volatile memory.

### BRIEF DESCRIPTION OF THE DRAWINGS

FIG. 1 is a timing chart illustrating one example of an operational outline of a semiconductor device according to a first embodiment.

FIG. 2 is a block diagram showing one example of transition of a rewrite operation of the semiconductor device according to the first embodiment.

FIG. 3 is a block diagram showing one example of a configuration of the semiconductor device according to the first embodiment.

FIG. 4 is a timing chart showing one example of a rewrite operation of the semiconductor device according to the first embodiment.

FIG. 5 is a timing chart showing one example of a rewrite operation of the semiconductor device according to the first embodiment.

FIG. 6 is a timing chart showing one example of a rewrite operation of the semiconductor device according to the first embodiment.

FIG. 7 is a timing chart showing one example of a rewrite operation of the semiconductor device according to the first embodiment.

FIG. 8 is a part of an example showing performance of the semiconductor device according to the first embodiment.

FIG. 9 is a diagram showing a relationship of rewritable areas in a semiconductor device according to a modification example of the first embodiment.

FIG. 10 is a diagram showing one example of transition of a rewrite operation of the semiconductor device according to the modification example of the first embodiment.

FIG. 11 is a block diagram showing one example of a configuration of a semiconductor device according to a second embodiment.

### DETAILED DESCRIPTION

For convenience, the following embodiments are divided into multiple sections or embodiments when necessary, but they are not independent of each other and one is part of the other unless otherwise specified. Or it is related to all modifications, details, supplementary explanations, etc. In addition, in the following embodiments, when referring to the number of elements (including the number, numerical value, amount, range, etc.), unless otherwise specified or clearly limited to a specific number in principle, is not limited to the specific number, and may be greater than or less than the specific number.

Furthermore, in the following embodiments, the constituent elements (including element steps, etc.) are not necessarily essential, unless otherwise specified or clearly considered essential in principle. Needless to say, similarly, in the following embodiments, when referring to the shape, positional relationship, etc. of components, etc., unless otherwise specified or in principle clearly considered otherwise, the shape is substantially the same. It shall include things that are similar or similar to, etc. This also applies to the above numerical values and ranges.

In addition, the circuit elements constituting each functional block of the embodiment are not particularly limited, but are formed on a semiconductor substrate such as single crystal silicon by known integrated circuit technology such as CMOS (complementary MOS transistor).

Hereinafter, the embodiments of the present disclosure will be described at details based on the drawings. Incidentally, in all the drawings for describing the embodiments, the same members are denoted by the same reference numerals, and a repetitive description thereof will be omitted. Further, a dimension ratio is emphasized for convenience of the description, and may be different from an actual dimension ratio.

### First Embodiment

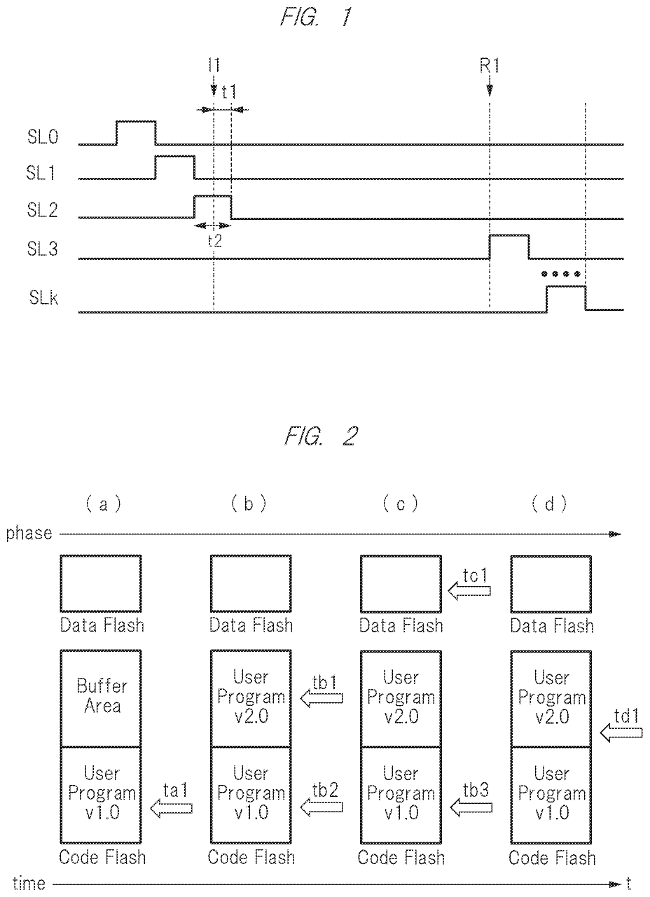

FIG. 1 is a diagram showing one example of a schematic timing chart of a semiconductor device according to a first embodiment. The timing chart of FIG. 1 is a diagram showing a relationship among application timing of a write voltage or an erase voltage applied to each of a plurality of source lines of a non-volatile memory, timing Il at which an interruption request signal to a write operation or an erase operation occurs, and timing R1 at which a return request signal is generated. Each source line of the plurality of source lines of the non-volatile memory is in a different region of the non-volatile memory and is used for dividing and selecting continuous regions.

Specifically, the semiconductor device in FIG. 1 shows applications of the write voltages or erase voltages to a source line SL0, which is a source line to be first selected, and a source line SL1, which is a source line to be secondly selected of the source line SL0. Therefore, the write operation or erase operation for the regions of the nonvolatile memory corresponding to source line SL0 and source line SL1 is completed. However, when a verify operation is required, the verify operation may be executed after the operations of the timing chart of FIG. 1 are completed.

Also, FIG. 1 shows a state in which an interruption request signal is generated at timing Il during application of a write voltage or erase voltage to a source line SL2. In this case, the semiconductor device completes the application of the write voltage or the erase voltage to the corresponding region of the nonvolatile memory corresponding to the source line SL2, and then maintains a suspended state for suspending the application of the write voltage or the erase voltage without applying a write voltage or erase voltage to a source line SL3, which is the next source line. After maintaining the suspended state, when a return request signal is generated at timing R1, the semiconductor device starts applying the write voltage or erase voltage to the source line SL3, which is the next source line. That is, the semiconductor device continues to apply the write voltage or erase voltage for a period of time t1 from the generation timing of the interruption request signal so as to satisfy a predetermined application width (application time: t2) of the write voltage or erase voltage. continue to be applied.

Further, if no interrupt request signal is generated during the application of the write voltage or erase voltage from the source line SL3 to a source line SLk (k is a positive integer equal to or greater than 4), the semiconductor device completes the applications from the source line SL3 to the source line SLk (k is a positive integer equal to or greater than 4).

As described above, the semiconductor device according to the present embodiment applies the write voltage or erase voltage in units of source lines, so that it is possible to shorten the interruption time when the interruption request signal is generated. In addition, since the semiconductor device according to the present embodiment completes the application of the write voltage or erase voltage in units of source lines and is shifted to the suspended state, the application width of the write voltage or erase voltage specified in advance (Application time: t2) can be reliably insured. Furthermore, the semiconductor device according to the present embodiment completes the application of the write voltage or erase voltage in units of source lines, is shifted to the suspended state, and restarts the application of the write voltage or erase voltage from the next source line. Therefore, it is possible to avoid an increase in stress on memory cells. That is, the limited number of writable times or erasable times for the nonvolatile memory is not wasted. Accordingly, the limitation on the number of times of interrupt processings used in a conventional technique can be removed. Furthermore, the semiconductor device according to the present embodiment completes the application of the write voltage or the erase voltage in units of source lines in response to one interruption request signal and then accepts the next interruption request signal, so that even if the interruption request signal is generated frequently, it is possible to avoid a situation where the write operation or erase operation does not progress.

FIG. 2 is a conceptual diagram showing one example of a rewrite state of a memory region of the nonvolatile memory corresponding to the timing chart of FIG. 1. Incidentally, in the present embodiment, rewriting is a term indicating at least one of writing and erasing, and the rewriting may include both writing and erasing.

As one example, given will be a description assuming that the semiconductor device including the nonvolatile memory in FIG. 2 is mounted on a vehicle or an IoT device. That is, FIG. 2 shows a confliction operation of the write/erase operations of the nonvolatile memory due to interruption request signals that occur during OTA firmware update (FOTA: Firmware Update Over-The-Air) of a semiconductor device.

FIG. 2A is a diagram conceptually showing regions of data flash (Data Flash) and code flash (Code Flash) as one example of a memory region of the nonvolatile memory in the present embodiment. For example, when the semiconductor device of the present embodiment is mounted on a vehicle and is used, the data flash may be used to rewrite field information such as vehicle speed and temperature. Therefore, the data flash may be used for rewrite operations of high-priority information. Also, the code flash may be used to rewrite firmware, which is a control program for a control device such as an ECU (Electronic Control Unit) in a vehicle. Accordingly, the firmware rewrite operation may take a long time. FIG. 2A shows a state in which firmware called user program v1.0 is written in a partial region of the code flash and shows that the firmware code at ta1 is being executed.

FIG. 2B shows a status in which during the execution of the firmware code at position tb2 of user program v1.0, user program v2.0 is executing an erase operation or write operation up to position tb1 in a code flash region different from that of the user program v1.0. For example, a state shown in FIG. 2B may be a state in which the user program v2.0 as an update program transmitted by wireless communication is halfway written during the operation of the ECU controlled by the user program v1.0. Incidentally, since an erase operation may be required before the write operation of the user program v2.0, the position tb1 indicates a position in the middle of the erase operation or write operation.

FIG. 2C shows a state in which during the execution of the firmware code at position tb3 of the user program v1.0 as firmware, an erase operation or write operation for writing the above-described high-priority field information to a data flash region is in progress. In this case, the erase operation or write operation for writing the user program v2.0 is temporarily suspended. Here, the shorter the interruption time from the generation of the interruption request signal for the user program v2.0 to the interruption of the erase operation or write operation for writing the user program v2.0, the shorter a latency for writing the high-priority information into the data flash region. That is, the processing capability of the semiconductor device is improved. Furthermore, since the write latency is shortened, a total time from the generation of the interruption request signal to the completion of the erase and write operations in the data flash region is shortened, so that this also means that a high-speed rewrite operation is made realizable.

FIG. 2D shows a state in which after the erase operation and the write operation for writing field information in the data flash region are completed and the writing of the user program v2.0 to the code flash region is completed, a control device such as an ECU of a vehicle is reset and execution of a user program v2.0, which is an update program, is started.

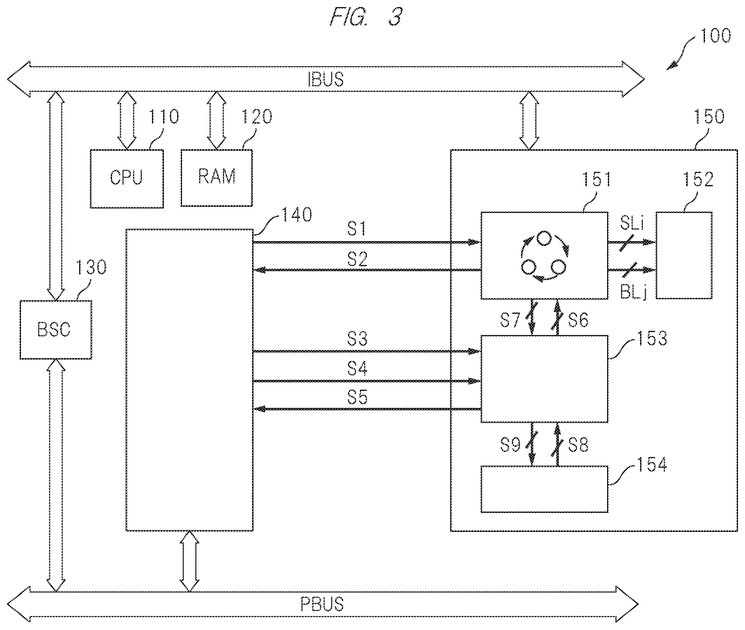

FIG. 3 is a block diagram showing a configuration example of a semiconductor device 100 according to the present embodiment. A semiconductor device 100 includes a CPU (Central Processing Unit) 110, a RAM (Random Access Memory) 120, a BSC (Bus State Controller) 130, a control unit 140, and a non-volatile memory 150.

The CPU 110 has a function of fetching a firmware code written in the non-volatile memory 150 and controlling the semiconductor device 100 and external electronic devices (not shown) connected to the semiconductor device 100 according to the firmware.

The RAM 120 has a function of temporarily storing information such as information that the CPU 110 generates by executing the firmware or information written in the non-volatile memory 150.

The BSC 130 has a function of switching between an internal bus (IBUS) and a peripheral bus (PBUS) to switch the bus accessible by the CPU 110. For example, when the CPU 110 reads the information written to non-volatile memory 150, the BSC 130 functions to allow the CPU 110 to access the IBUS. Also, for example, when the CPU 110 issues an instruction to execute an erase operation or write operation to the non-volatile memory 150, the BSC 130 functions so that the CPU 110 can access the control unit 140 via the PBUS.

When control unit 140 receives the instruction, which executes the erase or write operation to the non-volatile memory 150, from the CPU 110 via the PBUS, the control unit 140 outputs an erase mode signal and/or write mode signal S1 to a rewrite sequencer 151, which will be described later. Incidentally, as described above, the term “rewrite” is used in this specification as a term that includes either erasing or writing, or both erasing and writing.

After outputting the erase mode signal and/or the write mode signal S1 and before receiving a rewrite voltage application completion signal S2 from the rewrite sequencer 151, the control unit 140 may receive a rewrite instruction of high-priority information from the CPU 110. In this case, the control unit 140 outputs a rewrite suspension request signal S3 to a rewrite suspension/recovery control circuit 153, which will be described later. Further, when the control unit 140 receives an active rewrite voltage application stop flag S5 from a rewrite suspension/recovery control circuit 153 and then finishes writing the information with high priority, the control unit 140 outputs the rewrite recovery request signal S4 to the rewrite suspension/recovery control circuit 153. Incidentally, the writing of information with high priority is started by the erase mode signal and/or write mode signal S1, and the control unit 140 can recognize the completion of the writing of the high-priority information by receiving the rewrite voltage application completion signal S2.

The non-volatile memory 150 includes a rewrite sequencer 151, a non-volatile memory cell array 152, a rewrite suspension/recovery control circuit 153, and a rewrite information holding circuit 154.

When the rewrite sequencer 151 receives the erase mode signal and/or write mode signal S1 from the control unit 140, it enters the erase mode and/or write mode and executes the erase mode and/or write mode. The erase mode may include an application preparation step of an erase voltage, and operations such as an application operation of an erase voltage and a verify operation of erase. In addition, the write mode may include an application preparation stage of a write voltage, and operations such as an application operation of a write voltage and a verify operation of write. Also, in the write sequencer 151, a region for executing the erase and/or write of the non-volatile memory cell array 152 is determined by the source lines SLi (i is 0 or a positive integer) and the bit lines BLj (j is 0 or a positive integer).

One example of the non-volatile memory cell array 152 is a flash memory. In the non-volatile memory cell array 152, a region for executing the erase and/or write operations is selected by the source lines, the bit lines, and the like. The source line becomes active by applying an erase voltage in an erase operation and/or a write voltage in a write operation. Incidentally, in the present embodiment, the operation of the semiconductor device 100 will be described mainly based on the operation of the source line.

When the rewrite suspension/recovery control circuit 153 receives from the control unit 140 a rewrite suspension request signal S3 indicating a rewrite request for other information having a higher priority than the current information while the non-volatile memory cell array 152 is rewriting information, it has a function of executing the following operation. That is, the rewrite suspension/recovery control circuit 153 has a function of temporarily suspending the rewrite operation that is being executed. In addition, the rewrite suspension/recovery control circuit 153 has a recovery function of resuming the suspended rewrite operation after temporarily suspending the rewrite operation. However, the operation of the rewrite suspension/recovery control circuit 153 differs depending on reception timing of the rewrite suspension request signal S3 from the control unit 140. Here, an operation of the rewrite suspension/recovery control circuit 153 that receives the rewrite suspension request signal S3 during the execution of the rewrite operation with the source line selected will be described.

Specifically, when temporarily suspending the rewrite operation that is being executed, the rewrite suspension/recovery control circuit 153 temporarily suspends the rewrite operation after completing the application of the voltage applied to the selected source line. In other words, the rewrite suspension/recovery control circuit 153 continues to apply the applied voltage to be applied to the selected source line without executing a suspension operation for a predetermined time to be applied to the selected source line. Then, the rewrite suspension/recovery control circuit 153 temporarily suspends the rewrite operation before applying an applied voltage to be applied to the source line to be selected next. After temporarily suspending the rewrite operation, the rewrite suspension/recovery control circuit 153 outputs to the rewrite sequencer 151 a rewrite voltage application start/stop signal S6 in which information indicating a rewrite voltage application stop is active. When the rewrite sequencer 151 receives the rewrite voltage application start/stop signal S6, it outputs identification information S7 of the source line to be selected next to the rewrite suspension/recovery control circuit 153. The rewrite suspension/recovery control circuit 153, which has received identification information S7 of the source line to be selected next, outputs as S9 the identification information S7 to a rewrite information holding circuit 154. Further, the rewrite suspension/recovery control circuit 153 activates a rewrite voltage application stop flag S5 and outputs the rewrite voltage application stop flag S5 to the control unit 140.

Further, upon receiving a rewrite return request signal S4 from the control unit 140, the rewrite suspension/recovery control circuit 153 reads out identification information S8 of the source line to be selected next from the rewrite information holding circuit 154, and output a rewrite voltage application start/stop signal S6 including the identification information to the rewrite sequencer 151.

The rewrite information holding circuit 154 has a function of receiving identification information S9 of the source line to be selected next from the rewrite suspension/recovery control circuit 153 and storing the identification information. Further, the identification information stored in the rewrite information holding circuit 154 can be read by the rewrite suspension/recovery control circuit 153 that receives the rewrite recovery request signal S4.

(Difference of Operation Mode due to Reception Timing of Write Suspension Request Signal S3)

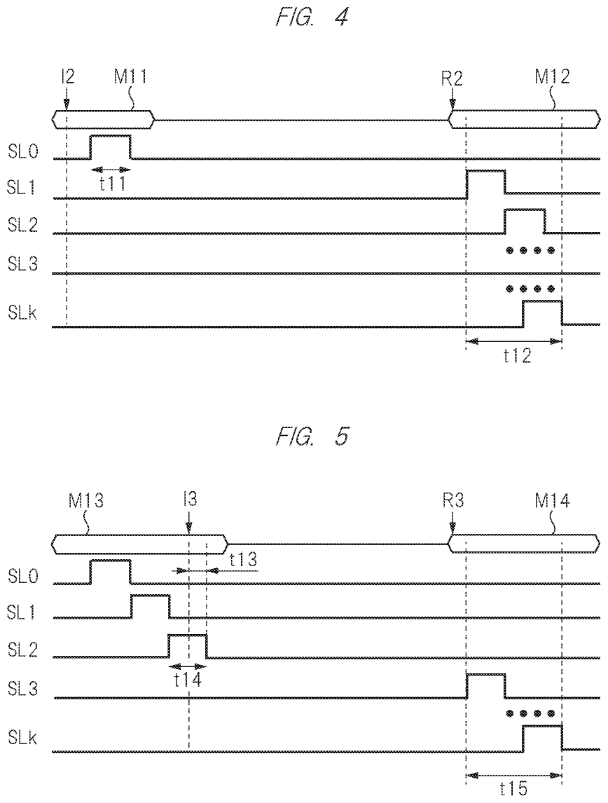

FIGS. 4 to 7 show differences in operation modes of the semiconductor device 100 when the rewrite suspension request signal S3 is generated at different timing in the rewrite mode.

FIG. 4 shows an operation of the semiconductor device 100 when the semiconductor device 100 is the rewrite mode M11, but the rewrite suspension request signal S3 is inputted to the rewrite suspension/recovery control circuit 153 before the rewrite voltage is applied to the source line SL0. When the rewrite suspension request signal S3 is inputted to the rewrite suspension/recovery control circuit 153 before the rewrite voltage is applied to the source line SL0, the semiconductor device 100 executes a processing of a voltage application sequence such as a power supply setup for applying the rewrite voltage regardless of the input of the rewrite suspension request signal S3. Then, the semiconductor device 100 selects the top source line (SL0) of the rewrite region of the non-volatile memory cell array 152 and applies the rewrite voltage. An application period of the rewrite voltage is a predetermined rewrite period (t11) for rewriting. In the semiconductor device 100, after applying the rewrite voltage during the rewrite period, the rewrite suspension/recovery control circuit 153 stops applying the rewrite voltage, activates a rewrite voltage application stop flag S5, and outputs the rewrite voltage application stop flag S5 to the control unit 140. The rewrite suspension/recovery control circuit 153 inputs, from the rewrite sequencer 151, identification information of a second source line (SL1) to which the rewrite voltage is to be applied next to the top source line (SL0), and outputs the identification information to the rewrite information holding circuit 154. The rewrite information holding circuit 154 stores the identification information of the second source line (SL1).

Further, in FIG. 4, when the rewrite recovery request signal S4 is inputted from the control unit 140 to the rewrite suspension/recovery control circuit 153 at timing R2, the semiconductor device 100 shifts to a rewrite mode M12. Then, the rewrite suspension/recovery control circuit 153 reads out the identification information of the second source line (SL1) from the rewrite information holding circuit 154. The identification information of the second source line (SL1) is included in a rewrite voltage application start/stop signal S6 and is inputted from the rewrite suspension/recovery control circuit 153 to the rewrite sequencer 151. The rewrite sequencer 151 selects the second source line (SL1) and applies a rewrite voltage to the second source line (SL1). If the rewrite suspension request signal S3 is not inputted to the rewrite suspension/recovery control circuit 153 until the last source line (SLk (k is an integer equal to or greater than 4)), the rewrite sequencer 151 causes the application of the rewrite voltage up to the last source line (SLk) to end. Time t12 indicates a time from the start of application of the rewrite voltage to the selected second source line (SL1) to the end of application of the rewrite voltage to the last source line (SLk).

FIG. 5 shows an operation mode of the semiconductor device 100 when the semiconductor device 100 is in the rewrite mode M13 during and the rewrite suspension request signal S3 is inputted to the rewrite suspension/recovery control circuit 153 at timing 13 during the application of the rewrite voltage to the selected source line SL2. Incidentally, the selected source line is not limited to the source line SL2, and the present embodiment can be applied when any one of the source lines SL0 to SLk-1 is selected. The application period of the rewrite voltage is a predetermined rewrite period (t14) for rewriting. That is, when any one of the source lines SL0 to SLk-1 is selected and even if the rewrite suspension request signal S3 is inputted, the rewrite suspension/recovery control circuit 153 causes the rewrite sequencer 151 to apply the rewrite voltage until the rewrite period of the selected source line ends. In the semiconductor device 100, after applying the rewrite voltage during the rewrite period, the rewrite suspension/recovery control circuit 153 stops applying the rewrite voltage, activates the rewrite voltage application stop flag S5, and outputs the rewrite voltage application stop flag S5 to the control unit 140. The rewrite suspension/recovery control circuit 153 inputs from the rewrite sequencer 151 identification information of a fourth source line (SL3) to which the rewrite voltage is to be applied next to the third source line (SL2), and outputs the identification information to the rewrite information holding circuit 154. The rewrite information holding circuit 154 stores, as a source line to which the rewrite voltage is to be applied next, the identification information of any one of the source lines SL1 to SLk.

Further, in FIG. 5, when the rewrite recovery request signal S4 is inputted from the control unit 140 to the rewrite suspension/recovery control circuit 153 at timing R3, the semiconductor device 100 shifts to the rewrite mode M14. Then, the rewrite suspension/recovery control circuit 153 reads out the identification information of the fourth source line (SL3) from the rewrite information holding circuit 154. The identification information of the fourth source line (SL3) is included in the rewrite voltage application start/stop signal S6 and is inputted from the rewrite suspension/recovery control circuit 153 to the rewrite sequencer 151. The rewrite sequencer 151 selects the fourth source line (SL3) and applies a rewrite voltage to the fourth source line (SL4). If the rewrite suspension request signal S3 is not inputted to the rewrite suspension/recovery control circuit 153 until the last source line (SLk (k is an integer equal to or greater than 4)), the rewrite sequencer 151 ends the application of the rewrite voltage until the last source line (SLK). Time t15 indicates a time from start of application of a rewrite voltage to a source line to be selected next to the source line, to which the rewrite suspension request signal S3 is inputted during the rewrite operation, to the end of the application of the rewrite voltage of the last source line (SLk).

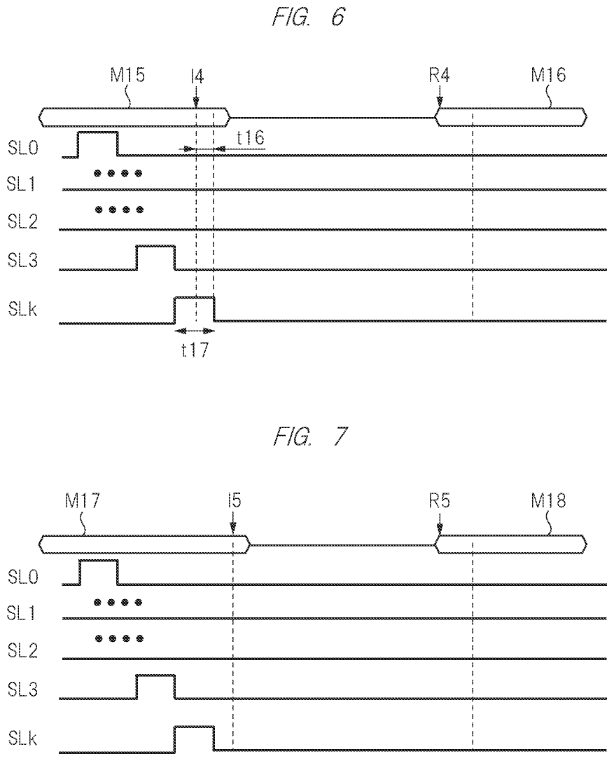

FIG. 6 shows an operation mode of the semiconductor device 100 when the semiconductor device 100 is in a rewrite mode M15 and the rewrite suspension request signal S3 is inputted to the rewrite suspension/recovery control circuit 153 at timing 14 during the application of the rewrite voltage to the selected last source line SLk. When the last source line SLk is selected and even if the rewrite suspension request signal S3 is inputted, the rewrite suspension/recovery control circuit 153 continues applying the rewrite voltage to the rewrite sequencer 151 until the rewrite period of the selected last source line ends. In the semiconductor device 100, after the rewrite voltage is applied during the rewrite period, the rewrite suspension/recovery control circuit 153 stops the application of the rewrite voltage, deactivates the rewrite voltage application stop flag S5, and outputs the inactive rewrite voltage application stop flag S5 to the control unit 140. Incidentally, in this case, the rewrite suspension/recovery control circuit 153 does not output the identification information S9 of the source line to the rewrite information holding circuit 154, so that the rewrite information holding circuit 154 does not store new information. Further, the control unit 140, which has received the inactive rewrite voltage application stop flag S5, starts a rewrite mode M16 after writing of new information generating the rewrite suspension request signal is finished, and completes during the rewrite mode M16 the verification operation suspended by the rewrite suspension request signal.

FIG. 7 shows an operation mode of the semiconductor device 100 when the semiconductor device 100 is in a rewrite mode M17 and the rewrite suspension request signal S3 is inputted to the rewrite suspension/recovery control circuit 153 at timing 15 after the application of the rewrite voltage to the selected last source line SLk is finished. The semiconductor device 100 deactivates the rewrite voltage application stop flag S5 and outputs the inactive rewrite voltage application stop flag S5 to the control unit 140. Also in this case, the rewrite suspension/recovery control circuit 153 does not output identification information S9 of the source line to the rewrite information holding circuit 154, so that the rewrite information holding circuit 154 does not store new information. Further, the control unit 140, which has received the inactive rewrite voltage application stop flag S5, starts a rewrite mode M18 after end of writing of new information generating the rewrite suspension request signal is generated, and completes during the rewrite mode M18 the verification operation of the information suspended by the rewrite suspension request signal.

(Experimental Example)

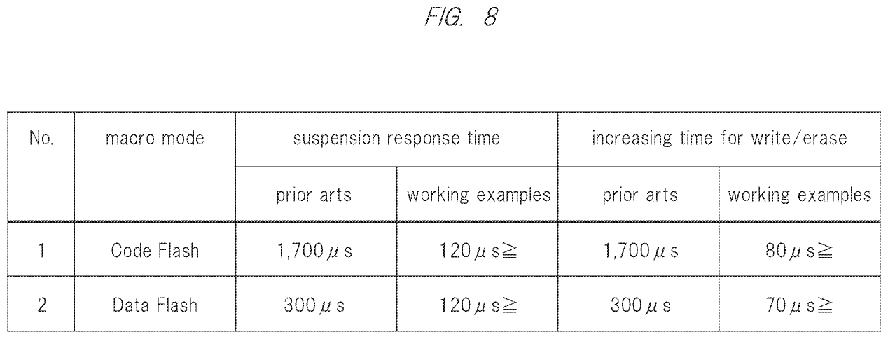

FIG. 8 shows results of measuring required time in a code flash area (No. 1) and a data flash area (No. 2) of the semiconductor device 100 capable of executing the above operations. The required time is indicated by two types of time. A first of the two types of time is a suspend response time (suspension response time). The suspend response time is a time from output of the rewrite suspension request signal S3 to the information in the rewrite mode to completion of the application of the rewrite voltage to the selected source line and the completion of the suspension processing. Therefore, the suspend response time is also a rewrite prohibition period (interruption time) during which rewriting to the code flash area or data flash area by other information is prohibited.

The suspend response time in the code flash area (No. 1) in an upper row of FIG. 8 was about 1700 μs of the conventional semiconductor device (prior art), while being about 120 μs or less in the experimental example (working example) of the semiconductor device according to the present embodiment. Further, the suspend response time in the data flash area (No. 2) in a lower row of FIG. 8 was about 300 μs of the conventional semiconductor device (prior art), while being 120 μs or less of the experimental example (working example) of the semiconductor device according to the present embodiment. Therefore, the semiconductor device 100 of the present embodiment can significantly shorten the suspend response time in the non-volatile memory.

A second of the two types of time is an increasing time for write operation/erase operation (increasing time for write/erase). The increasing time for write/erase is a time from completion of application of the rewrite voltage to the selected source line to completion of the suspension processing, generation of the rewrite recovery request signal S4, and completion of the rewrite recovery processing.

The increasing time of write/erase in the code flash area (No. 1) in an upper row of FIG. 8 was about 1700 μs in the conventional semiconductor device (prior art), while being 80 about 80 μs in the embodiment (working example) of the semiconductor device 100 according to the present embodiment. Also, the increasing time of write/erase in the data flash area (No. 2) in a lower row of FIG. 8 was about 300 μs in the conventional semiconductor device (prior art), while being about 70 μs or less in the embodiment (working example) of the semiconductor device 100 according to the present embodiment. Therefore, the semiconductor device 100 according to the present embodiment can significantly reduce the increasing time for write/erase in the non-volatile memory.

According to the semiconductor device 100 according to the present embodiment described above, even if competition of the write operations and/or erase operations occurs in a region of the non-volatile memory cell array 152 such as a flash memory, the rewrite inhibition period can be greatly shorted. That is, it is possible to greatly shorten the interruption processing (suspend response time) of the write operation and/or erase operation. In addition, it is possible to greatly suppress the increasing time for write and/or erase, the increasing time being caused by the suspension processing of the write operation and/or erase operation.

Further, according to the semiconductor device 100 according to the present embodiment described above, the erase voltage or write voltage to the once selected source line continues to be applied for a predetermined period regardless of the generation of the rewrite suspension request signal. Therefore, the region of the non-volatile memory cell array 152 is not subjected to unnecessary stress, so that the number of times of the application of the erase voltage or write voltage guaranteed in the region of the non-volatile memory cell array 152 is not used wastefully.

Furthermore, according to the semiconductor device 100 according to the present embodiment described above, it is possible to remove the limitation on the number of times of use of the high-speed suspension processing operation, which is limited in the conventional technology.

Furthermore, according to the semiconductor device 100 according to the present embodiment described above, even if the rewrite suspension request signal is repeatedly generated in a short period of time, the semiconductor device 100 according to the present embodiment completes the erase operation or write operation on the selected source line and then accepts the next rewrite suspension request signal. Therefore, the semiconductor device 100 according to the present embodiment is configured to be able to continue performing a rewrite operation of information to be rewritten even if the suspension processing is repeated.

Furthermore, according to the semiconductor device 100 according to the present embodiment described above, a plurality of control units 140 do not need to be mounted in order to respond to the rewrite suspension request, so that an increase of areas and an increase in costs of the semiconductor device 100 can be suppressed.

(Modification Example of First Embodiment)

In the above-described embodiments, the operation of the semiconductor device 100 according to the present embodiment has been described mainly in a case where the rewrite operation to the data flash area is generated during the rewrite operation of the code flash area. However, the suspension processing operation of the semiconductor device 100 according to the present embodiment does not depend on the region of the non-volatile memory cell array 152.

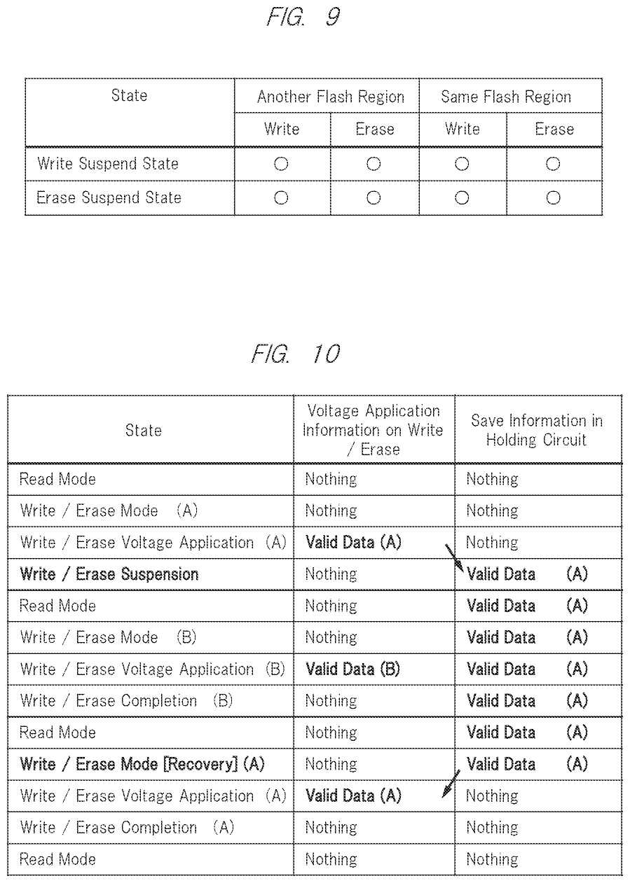

FIG. 9 is a diagram showing that a suspension processing operation of the semiconductor device 100 according to the preset embodiment does not depend on the region of the non-volatile memory cell array 152. As described above, a separate flash area in FIG. 9 indicates whether the write operation and the erase operation can be interrupted between the code flash area and the data flash area. FIG. 9 shows that write operation and erase operation are possible in a separate flash area in the write suspend state. Furthermore, FIG. 9 shows that the write operation and erase operation are possible in a separate flash area in the erase suspend state.

The same flash area in FIG. 9 indicates whether the write operation and erase operation can be interrupted in the code flash area or data flash area. FIG. 9 shows that the write operation and erase operation are possible in the same flash area in the write suspend state. Furthermore, FIG. 9 shows that the write operation and erase operation are possible in the same flash area in the erase suspend state.

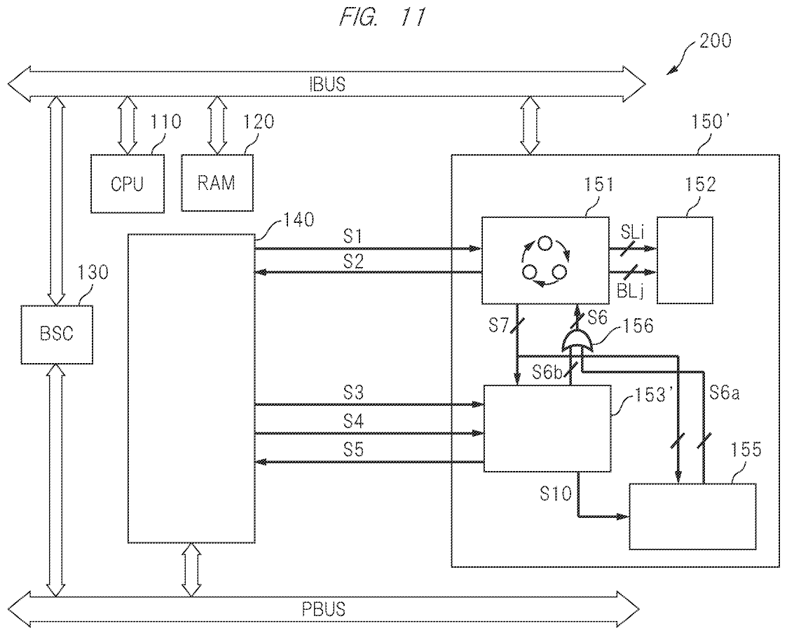

FIG. 10 is a diagram showing use and holding statuses of valid data (identification information of a source line to be selected next when an interrupt of a rewrite (write/erase) operation of information B, which has a higher priority than that of information A, occurs during the rewrite (write/erase) operation of the information A in the same flash area.

Starting from a top row of FIG. 10, the semiconductor device 100 is first in a read mode. Next, when an interrupt for writing and/or erasing of the information A occurs, the semiconductor device 100 shifts to a write/erase mode of the information A. Thereafter, when the semiconductor device 100 enters a write/erase voltage application state, identification information of a source line to be selected next to the source line to which the write/erase voltage is applied is generated as valid data (A). Here, when the interrupt of the write and/or erase of the information A occurs, the semiconductor device 100 interrupts the write/erase of the information A. further, when the write/erase of the information A is interrupted, the valid data (A) is saved in the rewrite information holding circuit 154 to prepare for a write/erase recovery operation of the information A.

In FIG. 10, when the valid data (A) is saved in the rewrite information holding circuit 154, the semiconductor device 100 temporarily shifts to a read mode and then shifts to a write/erase mode of the information B. Then, the semiconductor device 100 applies the write/erase voltage of the information B up to the last source line according to valid data (B) on the source line to which the write/erase voltage of the information B is applied, and ends the write/erase operation. No valid data (B) remains in the rewrite sequencer 151, and the valid data (A) is saved in the rewrite information holding circuit 154.

In FIG. 10, when the write/erase operation of the information B is completed, the semiconductor device 100 temporarily shifts to the read mode and then returns to the write/erase mode of the information A. When the semiconductor device 100 returns to the write/erase mode of the information A, the semiconductor device 100 reads the valid data (A) saved in the rewrite information holding circuit 154 and resumes the write/erase mode of the information A. When the semiconductor device 100 resumes the application of the write/erase voltage by using the valid data (A), the semiconductor device 100 applies the write/erase voltage of the information A up to the last source line and ends the write/erase operation. Further, when the valid data (A) saved in the rewrite information holding circuit 154 is read, the valid data saved in the rewrite information holding circuit 154 is erased. After completing the write/erase operation, the semiconductor device 100 shifts to the read mode and starts or continues a control operation according to firmware stored in the non-volatile memory.

As described above, the valid data (B) can indicate a source line(s) other than a rewrite region of the information A. Therefore, the valid data (A) and the valid data (B) can be used as identification information indicating source lines in different areas of the same flash memory. That is, by arranging the rewrite information holding circuit 154 in the non-volatile memory 150, a write/erasing operation(s) can be performed in a different region from a region where the write/erase operation is suspended. The region and the other region that are relative here are intended to be arbitrary regions within the non-volatile memory cell array 152.

### Second Embodiment

FIG. 11 is a block diagram showing one example of a configuration of a semiconductor device 200 according to a second embodiment. A different point from the semiconductor device 100 according to the first embodiment is that a rewrite control circuit 155 and an OR circuit 156 are added to a non-volatile memory 150′ instead of the rewrite information holding circuit 154. In addition to the function of the rewrite suspension/recovery control circuit 153, a rewrite suspension/recovery control circuit 153′ further has a function of outputting a rewrite stop flag S10 to the rewrite control circuit 155.

The rewrite suspension/recovery control circuit 153′ receives the rewrite suspension request signal S3 from the control unit 140 and executes the rewrite suspension processing like the rewrite suspension/recovery control circuit 153 according to the first embodiment. Further, the rewrite suspension/recovery control circuit 153′ outputs a rewrite voltage application stop flag S5 to the control unit 140 when stopping the application of the rewrite voltage. Then, after temporarily interrupting the rewrite operation, the rewrite suspension/recovery control circuit 153′ outputs, as a rewrite voltage application start/stop signal S6 through the OR circuit 156 to the rewrite sequencer 151, a rewrite voltage application start/stop signal S6a that activates the information indicating the rewrite voltage application stop. Furthermore, after temporarily suspending the rewrite operation, the rewrite suspension/recovery control circuit 153′ outputs a rewrite stop flag S10 to the rewrite control circuit 155. In addition, when the rewrite suspension/recovery request signal S4 is inputted from the control unit 140, the rewrite suspension/recovery control circuit 153′ executes a rewrite suspension/recovery processing.

When the rewrite stop flag S10 is inputted from the rewrite suspension/recovery control circuit 153′, the rewrite control circuit 155 executes a write/erase operation to write information related to a new interrupt into the non-volatile memory cell array 152. The application and stop of the write voltage are executed by outputting as the write voltage application start/stop signal S6 a write voltage application start/stop signal S6b to the write sequencer 151 though the OR circuit 156. Also, the identification information of the source line is inputted from the rewrite sequencer 151 to the rewrite control circuit 155 and the rewrite suspension/recovery control circuit 153′.

According to a configuration of the semiconductor device 200 according to the second embodiment described above, instead of the rewrite information holding circuit 154, it is possible to provide two sets of control circuits that can apply the rewrite voltage. Therefore, when the suspend request is generated, the control circuit that is applying the rewrite voltage is temporarily stopped and another control unit is used for a write operation/erase operation to other regions of the non-volatile memory cell array 152 in which the suspend request is generated.

### Third Embodiment

A semiconductor device according to a third embodiment stops applying the rewrite voltage to the selected source line when the rewrite suspension request signal S3 is inputted to the selected source line during the application of the rewrite, and stores remaining time information of a rewrite voltage, which should have been applied to the source line, in the rewrite information holding circuit 154. Incidentally, in the rewrite information holding circuit 154, the identification information of the selected source line is also stored in association with remaining time information of the rewrite voltage. For example, a time obtained by subtracting a second time from a first time can be set as a remaining time of the rewrite voltage, the first time being a predetermined time during which the rewrite voltage is applied to the selected source line, the second time being a time at which the application to the rewrite voltage is interrupted by an input of the rewrite suspension request signal S3. Therefore, the semiconductor device according to the third embodiment stops the rewrite operation halfway through the application without completing the application of the rewrite voltage to the selected source line when the rewrite suspension request signal S3 is inputted during the application of the rewrite voltage to the selected source line. Then, when the rewrite recovery request signal S4 is inputted, the semiconductor device according to the third embodiment selects the source line to which the rewrite voltage has been stopped, applies the rewrite voltage for the remaining time of the rewrite voltage, and ends the rewrite operation to the source line. Further, the remaining time of the rewrite voltage can be configured to be counted with the minimum unit of a clock in which the semiconductor device is operating.

According to the semiconductor device according to the third embodiment described above, even if the competition of the write operations and/or erase operation occurs in the region of the non-volatile memory cell array 152 such as a flash memory, the rewrite inhibit period can be greatly shortened. That is, it is possible to greatly shorten the interruption time (suspend response time) of the write operation and/or erase operation. In addition, it is possible to greatly suppress the increasing time of write and/or erase, which is caused by the interruption processings of the write operation and/or erase operation.

Further, according to the semiconductor device according to the third embodiment described above, it is possible to divide the erase voltage or write voltage for the source line once selected and apply it for a predetermined period. Therefore, the non-volatile memory cell array 152 region is not subjected to unnecessary stress, so that the number of times of the application of the erase voltage or write voltage guaranteed in the non-volatile memory cell array 152 region is not used wastefully.

Furthermore, according to the semiconductor device 100 according to the third embodiment described above, it is possible to remove the limitation on the number of times of use of the high-speed interruption processing operation, which has been limited in the conventional technique.

Furthermore, according to the semiconductor device 100 according to the third embodiment described above, even if the rewrite suspension request signal is repeatedly generated in a short period of time, the present embodiment interrupts the erase operation or write operation of the selected source line halfway, accepts the next rewrite suspension request signal, and completes the erase operation or write operation by continuing from the interrupted operation. Therefore, the semiconductor device 100 according to the present embodiment is configured so that even if the suspension processing is repeated, the rewrite operation of the information to be rewritten can proceed without backtracking.

The invention made by the present inventor(s) has been specifically described above based on the embodiments, but the present invention is not limited to the above-described embodiments and, needless to say, can variously be modified without departing from the gist of the invention. Also, for example, the above-described embodiments have been described in detail in order to explain the present invention in an easy-to-understand manner, and are not necessarily limited to those having all the described configurations. Moreover, it is possible to add, delete, or replace a part of the configuration of the above-described embodiment to, from, or with another configuration.

What is claimed is:

1. A semiconductor device comprising an electrically writable or erasable non-volatile memory and a control circuit for executing mode control of a write operation and an erase operation of the non-volatile memory,
wherein the non-volatile memory includes:
a rewrite suspension/recovery control circuit: responding to a suspension request signal from the control unit that requests a suspension of a rewrite operation containing at least one of the write operation and the erase operation; responding to an operation for suspending an application of a write voltage or an erase voltage and a recovery request signal from the control unit that requests a recovery from the suspension of the rewrite operation; controlling an operation for recovery from the suspension of the application of the rewrite voltage or erase voltage; and outputting a rewrite interruption/return control circuit that outputs to the control circuit a voltage application stop flag at a voltage application stop of the write voltage or erase voltage, and
a rewrite information holding circuit that holds write position information for identifying a selection line to which a write voltage is applied at a response time of a suspension request signal or erase position information for identifying a selection line to which an erase voltage is applied at the response time of the suspension request signal, and
wherein the control unit responses to a suspension instruction when the non-volatile memory is in a write mode or an erase mode, transmits the suspension request signal of write to the rewrite suspension/recovery control unit, responds to a recovery instruction of the write mode or erase mode of the non-volatile memory suspended by the suspension request signal, and outputs a recovery request signal of the write to the rewrite suspension/recovery control unit when the voltage application stop flag outputted from the rewrite suspension/recovery control unit is active.

2. The semiconductor device according to claim 1,
wherein the rewrite suspension/recovery control unit:
in receiving the suspension request signal before an application of a write voltage or erase voltage to a first selection line to be selected in a write mode or erase mode, selects the first selection line, interrupts the write mode or erase mode after the application of the write voltage or erase voltage to the first selection line, and activates the voltage application stop flag to output it to the control unit;
in receiving the suspension request signal during the application of the write voltage or erase voltage to a selection line other than a last selection line to be selected in the write mode or erase mode, interrupts the write mode or erase mode after completion of the application of the write voltage or erase voltage to the selection line, and activates the voltage application stop flag to output it to the control unit;
in receiving the suspension request signal during the application of the write voltage or erase voltage to the last selection line to be selected in the write mode or erase mode, interrupts the write mode or erase mode after the completion of the application of the write voltage or erase voltage to the last selection line, and deactivates the voltage application stop flag to output it to the control unit; and
in receiving the suspension request signal after the application of the write voltage or erase voltage to the last selection line to be selected in the write mode or erase mode, deactivates the voltage application stop flag to output it to the control unit.

3. The semiconductor device according to claim 1,
wherein when the rewrite suspension/recovery control unit receives the suspension request signal before the application of the write voltage or erase voltage to the first selection line to be selected in the write mode or erase mode, the rewrite suspension/recovery control unit selects the first selection line and completes the application of the write voltage or erase voltage to the first selection line and, thereafter, the rewrite information holding circuit receives identification information of a selection line to be selected next to the first selection line from the rewrite suspension/recovery control unit and to stores it,
wherein when the rewrite suspension/recovery control circuit receives the suspension request signal during an application of a write voltage or erase voltage to a selection line other than the last selection line to be selected in the write mode or erase mode, the rewrite suspension/recovery control unit completes the application of the write voltage or erase voltage to the selection line and, thereafter, the rewrite information holding circuit receives identification information of a selection line to be selected next to the selection line from the rewrite suspension/recovery control unit and to stores it, and
wherein when the rewrite suspension/recovery control circuit receives the suspension request signal of the rewrite from the control unit, the rewrite suspension/recovery control circuit:
reads the identification information of a selection line to be selected next from the rewrite information holding circuit;
selects a next selection line to be selected next indicated by the identification information; and
applies the write voltage or erase voltage to the selection line.

4. The semiconductor device according to claim 1,
wherein the rewrite information holding circuit stores write time information from the application of the write voltage to the selection line to a suspension of the application in addition to the write position information, or,
wherein the rewrite information holding circuit stores erase time information from the application of the erase voltage to the selection line to a suspension of the application in addition to the erase position information, and
wherein when the rewrite suspension/recovery control circuit receives the recovery request signal, the rewrite suspension/recovery control circuit reads the write position information or write time information or the erase position information or erase time information from the rewrite information holding circuit, selects a selection line indicated by the write position information or erase position information, and applies the write voltage or erase voltage to the selection line for a remaining time to be applied to the selection line.

5. A semiconductor device having an electrically writable or erasable non-volatile memory and a control circuit for executing mode control of a write operation and an erase operation of the non-volatile memory,
wherein the non-volatile memory includes:
a rewrite suspension/recovery control circuit responding to a suspension request signal from the control unit that requests a suspension of a rewrite operation containing at least one of the write operation and the erase operation; responding to an operation for suspending an application of a write voltage or an erase voltage and a recovery request signal from the control unit that requests a recovery from the suspension of the rewrite operation; controlling an operation for recovery from the suspension of the application of the rewrite voltage or erase voltage; outputting a voltage application stop flag to the control unit at the voltage application stop of the write voltage or erase voltage, and outputting an active rewrite stop flag at the stop of the write operation or erase operation; and
when receiving the active rewrite stop flag, the rewrite suspension/recovery control circuit capable of controlling a write operation or erase operation to another region different from a region in which the write operation or erase operation is stopped.

6. The semiconductor device according to claim 1,
wherein the selectin line is a source line of the non-volatile memory, the source line is composed of a plurality of source lines, and each of the plurality of source lines corresponds to a different storage region.

7. The semiconductor device according to claim 6,
wherein the selection line further includes a bit line of the non-volatile memory.
